(19) United States
(12) Patent Application Publication
(10) Pub. No.: US 2020/0343470 A1
(43) Pub. Date: Oct. 29, 2020

(54) LIGHT EMITTING DEVICE AND A METHOD FOR COMPENSATING LIGHT EMITTING DEVICE POWER SUPPLY VOLTAGE DROP

(71) Applicant: INT TECH CO., LTD., HSINCHU COUNTY (TW)

(72) Inventor: KUO-CHENG HSU, TAICHUNG CITY (TW)

(21) Appl. No.: 16/394,274

(22) Filed: Apr. 25, 2019

(51) Int. Cl. H01L 51/52; H01L 27/32; G09G 3/3233

(52) U.S. Cl. CPC H01L 51/5203; H01L 27/3248; G09G 3/3233; H01L 27/3276

(57) ABSTRACT

The present disclosure provides a light emitting device. The light emitting device includes a first substrate and a second substrate below the first substrate. The light emitting device also includes a light sensing region in the second substrate, and a light emitting pixel over the first substrate. The light emitting pixel includes a first electrode having a recession concave downward to the second substrate. The light emitting pixel also includes a second electrode over the first electrode. The light emitting pixel also includes an organic layer disposed between the first electrode and the second electrode in a vertical direction. The recession is partially overlapped with the light sensing region in the vertical direction. A method for compensating light emitting device power supply voltage drop is also provided.

### TECHNICAL FIELD

The present disclosure is related to light emitting device and a method for compensating light emitting device power supply voltage drop, especially to an organic light emitting device with a light sensing region.

### BACKGROUND

Organic light emitting display (OLED) has been used widely in most high end electron devices, especially the Active Matrix type OLED (AMOLED). Each light-emitting element, i.e. pixel, in the AMOLED is independently controlled by Thin Film Transistor (TFT). The pixels require power supply signal line to load direct current output voltage (VDD) for driving. However, since the driving current for all the pixels are provided by the VDD, undesired resistance may exist, and causing power supply voltage drop (IR Drop). The IR Drop may cause current difference among different areas, resulting in the uneven brightness (mura) phenomenon.

In addition, the AMOLED generates light by passing current through organic material films. As time elapsed, the organic materials may become aged, meanwhile, the light emitting efficiency may reduce.

### SUMMARY

In the present disclosure, the light emitting units are formed by a photo sensitive material. The photo sensitive material is directly disposed on a substrate without a pixel defined layer. The pixel definition is realized by a photolithography process.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a top view of a portion of a light emitting device, in accordance with some embodiments of the present disclosure.

FIG. 2 illustrates a cross-sectional view along the line AA in FIG. 1, in accordance with some embodiments of the present disclosure.

FIG. 3 illustrates a cross-sectional view of a pixel of a light emitting device, in accordance with some embodiments of the present disclosure.

FIG. 4 illustrates a cross-sectional view of a pixel of a light emitting device, in accordance with some embodiments of the present disclosure.

FIG. 5 is a functional block diagram of a light emitting device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

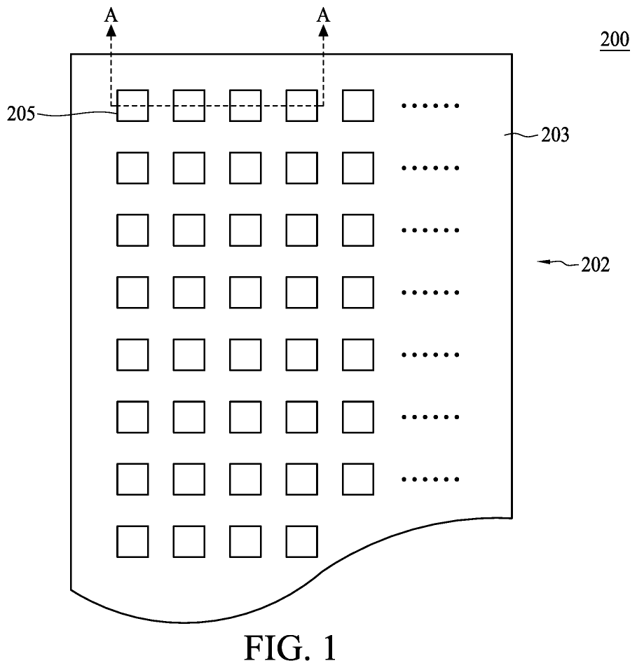

Referring to FIG. 1, FIG. 1 is a top view of a portion of a light emitting device 200, in accordance with some embodiments of the present disclosure. The light emitting device 200 can be a rigid or a flexible display. In some embodiments, the light emitting device 200 may include a substrate 202 and a light emitting layer 203 disposed thereon. In some embodiments, several conductive traces may be disposed in the substrate 202 and form circuitry to provide current to the light emitting layer 203. In some embodiments, the substrate 202 may include a TFT (thin film transistor) array.

In some embodiments, the light emitting layer 203 may include many light emitting units 205. In some embodiments, the light emitting units 205 may also be referred as light emitting pixels or pixels.

In some embodiments, the light emitting units 205 are configured as mesa disposed on the substrate 202. In some embodiments, the light emitting units 205 are configured to be in recesses of the substrate 202. In some embodiments, the light emitting units 205 can be arranged in an array. Each independent light emitting unit is separated from other adjacent light emitting units. In some embodiments, the separation distance between two adjacent light emitting units is between about 2 nm and about 100 um. In some embodiments, the separation distance is controlled to be at least not greater than about 50 um so that the density of the light emitting units 205 can be designed to be at least more than 700 ppi or 1200 ppi. In some embodiments, a light emitting unit 205 has a width, w, being between about 2 nm and about 500 um. In some embodiments the width, w, is not greater than about 2 um.

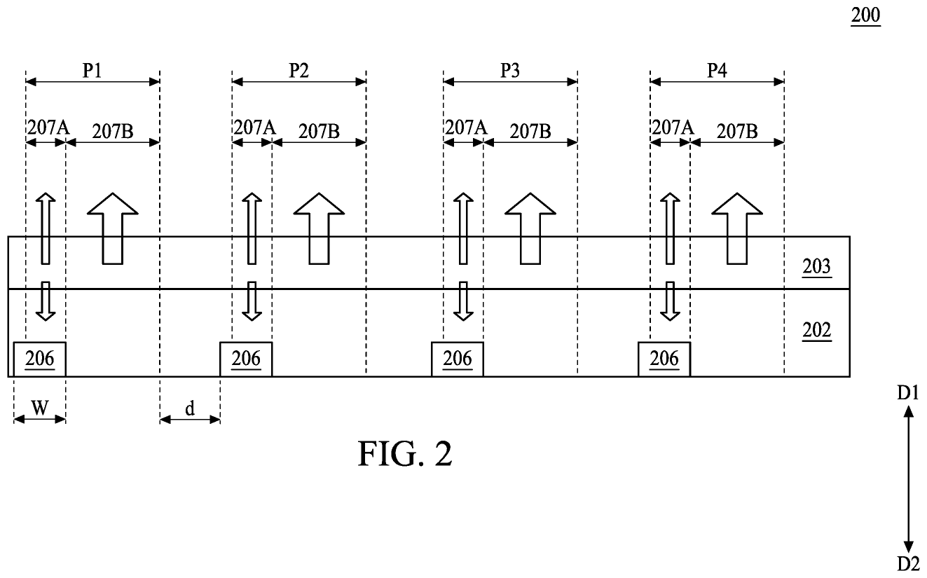

Referring to FIG. 2, FIG. 2 illustrates a cross-sectional view along the line AA in FIG. 1, in accordance with some embodiments of the present disclosure. The light emitting device 200 includes a plurality of pixels P1 to P4, each including a first portion 207A and a second portion 207B.

In FIG. 2, the light emitting device 200 is a top emission type, and an image of the pixels is realized in a direction opposite to the substrate 202, hereafter, “D1”. The users may observe an image in the direction D1.

In the first portion 207A and the second portion 207B, lights emitted from the plurality of pixels P1 to P4 may propagate in the direction D1. In some embodiments, the first portion 207A and the second portion 207B are integrated. The users may be able to observe the image from the first portion 207A and the second portion 207B. In some embodiments, in the first portion 207A, the lights are allowed to propagate in the direction D1 and a direction toward the substrate 202, hereafter, “D2”. In some embodiments, in the second portion 207B, the lights are not allowed to propagate in the direction D2.

In some embodiments, the light emitting device 200 may include a light sensing region 206 in the substrate 202. In some embodiments, the light emitting device 200 includes several light sensing regions 206 in the substrate 202.

For example, the light emitting device 200 may include several light sensing regions 206 and each individual light sensing region 206 vertically aligns with a corresponding first portion 207A of each pixel. In some embodiments, each individual light sensing region 206 covers an area of a corresponding first portion 207A of each pixel.

In some embodiments, the light sensing region 206 can be further extended under the second portion 207B. Hence, a partial overlap between the second portion 207B and the light sensing region 206 is observed in top view perspective. In some embodiments, the overlapping area between the second portion 207B and the light sensing region 206 is less than about 70% of each pixel area. The extension of the light sensing region 206 may be configured to receive the light emitted from the corresponding light emitting pixel Pₓ. In some embodiments, the light sensing region 206 can be inside the first portion 207A. In some embodiments, the light sensing region 206 and the second portion 207B are staggered in the direction D1. In some embodiments, a width, w, of each light sensing region 206 can be designed in consideration of several variables, such as the overlapping area, the ability to receive the light, and the cost.

As mentioned, above, in the second portion 207B, the lights are allowed to propagate in the direction D2. In other words, a portion of lights emitted from the pixels P1 to P4 are travelling through the first portion 207A then arrive on the light sensing regions 206. The above arrangement to each pixel to have two different light transmission portions gives a designer allowances to insert an in-situ one-on-one sensor for each light emitting pixel. One advantage is to use the embedded in-situ sensor to collect backlit light from its corresponding pixel without sacrificing the effective light emitting area of the light emitting device. The collected backlit light is processed by the in-situ sensor in order to monitor real time performance of the pixel. Therefore, a compensation or repair can be introduced to a degraded or malfunction pixel without shutting the light emitting device 200.

Because the sensor region 206 is arranged underneath the pixel, the luminous flux generated from each pixel and entering into user's eyes is not reduced by the in-situ sensor region. The lights generated from the pixel but above the first portion 207A may lose in one direction but the visual impact to the user can be ignored if the area ratio between the first portion 207A and second portion 207B is well designed. Further, in some embodiment, the pixels are shrinked through technique as described in U.S. Pat. No. 10,193,098B2, more areas can be allocated for placing pixels, thus the trade off to partition a pixel into multi-portions having different configurations is a reasonable approach. In some embodiments, a gap, d, represents a separation distance between two adjacent pixels. In some embodiments, gap, d, is between about 2 nm and about 100 um. In some embodiments, the gap, d, is controlled to be at least not greater than about 50 um so that the density of the units can be designed to be at least more than 700 ppi or 1200 ppi.

In some embodiments, a first sub-pixel, a second sub-pixel, and a third sub-pixel emit different colored lights and can be arranged in the first portion 207A and the second portion 207B. The first sub-pixel, the second sub-pixel, and the third sub-pixel can respectively emit red light, green light, and blue light. In the second portion 207B, the different colored lights may propagate in the direction D1. In the first portion 207A, the different colored lights may propagate both in the direction D1 and the direction D2. Hence, the sensor region 206 may be able to collect backlit light of different colors for monitoring real time performance of different colored lights. However, an embodiment is not limited thereto and any color combination is possible as long as white light is emitted.

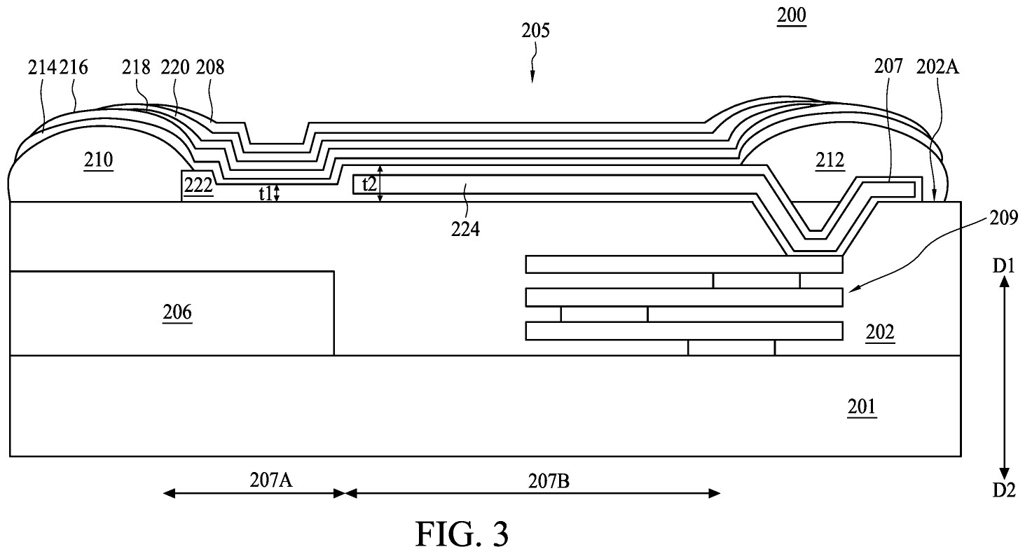

Referring to FIG. 3, FIG. 3 illustrates a cross-sectional view of a pixel of the light emitting device 200, in accordance with some embodiments of the present disclosure. As shown in FIG. 3, the light emitting device 200 may include a TFT layer 201, the substrate 202 over the TFT layer 201, the light emitting layer over the substrate 202, and an encapsulation layer over the light emitting layer. In some embodiments, the light emitting device 200 may include a light sensing region 206 in the substrate 202. In some embodiments, the light emitting device 200 may include several bumps over the substrate 202. In some embodiments, the light sensing region 206 senses lights such as emission lights. In some embodiments, the light sensing region 206 may include a photodiode.

In some embodiments, each independent light emitting unit 205 is separated from other adjacent light emitting units 205 by the several bumps, such as the bumps 210 and 212 shown in the FIG. 3. The bumps are also called pixel defined layer (PDL). The bumps can be formed in different types of shape. In some embodiments, the bumps have a curved surface. In some embodiments, the shape of the bumps is trapezoid.

In some embodiments, each independent light emitting unit 205 includes a first electrode 207, a second electrode 208 over the first electrode 207, and organic layers between the first electrode 207 and the second electrode 208. In some embodiments, the first electrode 207, the second electrode 208, and the organic layers are stacked on the substrate 202 along the direction D1. In some embodiments, the light sensing region 206 may between the TFT layer 201 and the first electrode 207.

In some embodiments, the first electrode 207 is partially covered by the bumps 210 and 212. In some embodiments, the bumps 210 and 212 are partially covered by organic layers and the second electrode 208.

In some embodiments, several first electrodes 207 are disposed over a top surface 202A of the substrate 202. In some embodiments, each first electrode 207 is configured to be connected to a control circuit 209 embedded in the substrate 202 at one side and to be in contact with a light emitting material at the other side. In some embodiments, the pattern of the first electrode array is designed for the pixel arrangement.

A part of the emission lights is allowed to be received on the light sensing portion 206, and the light sensing region 206 may communicate with the control circuit 209. If the brightness of the emission light is detected to be different than a standard value, the circuitry in the TFT layer 201 may be regulated to increase the voltage of the light emitting unit 205. In some embodiments, the electric current from the circuitry in the TFT layer 201 can be introduced to the first electrode 207 through the control circuit 209 embedded in the substrate 202.

In some embodiments, the organic layers includes a first type carrier injection layer 214, a first type carrier transportation layer 216, an organic emissive layer (EM) layer 218, and a second type carrier transportation layer 220.

In some embodiments, the first type carrier injection layer 214 is an electron injection layer (EIL) and the first type carrier transportation layer 216 is an electron transportation layer (ETL). In some embodiments, the first type carrier injection layer 214 is a hole injection layer (HIL) and the first type carrier transportation layer 216 is a hole transportation layer (HTL). In some embodiments, the second type carrier transportation layer 220 can be a hole or electron transportation layer 220. In some embodiments, the second type carrier transportation layer 220 and the first type carrier transportation layer 216 is respectively configured for opposite types of charges. In some embodiments, a second type carrier injection layer (not shown in the figures) is further disposed over the second type carrier transportation layer 220. In some embodiments, the EM layer 218 is configured to emit a light of a range of wavelength.

In some embodiments, the first electrode 207 and the second electrode 208 are respectively employed as the anode and the cathode of the light emitting device 200.

Under certain voltage driving, the electron and the hole are respectively rejected into the electron and hole transporting layers 216 and 220 from the cathode and the anode. The electron and the hole respectively migrate from the electron and hole transporting layers 216 and 220 to the emitting layer 218 and bump into each other in the emitting layer 218 to form an exciton to excite the emitting molecule.

In some embodiments, each first electrode 207 includes a first portion 207A and a second portion 207B. In some embodiments, each first electrode 207 includes a layer 222 transparent to the light of a range of wavelength, and a layer 224 opaque to the light of a range of wavelength. In some embodiments, the layer 224 acts as a reflector to reflect light, which is emitted from the emitting layer 218 and toward the layer 224. For examples, the light may be a red light with a wavelength about 625 nm, a green light with a wavelength about 530 nm, or a blue light with a wavelength about 430 nm.

In some embodiments, the layer 222 includes transparent conducting films, such as indium tin oxide (ITO), fluorine doped tin oxide (FTO), or doped zinc oxide (ZnO). Alternatively, the layer 222 may include wider-spectrum transparent conductive oxides (TCOs), conductive polymers, metal grids and random metallic networks, carbon nanotubes (CNT), graphene, nanowire meshes and ultra-thin metal films. In some embodiments, the layer 222 is transparent to the light emitted from the emitting layer 218. In other words, the light emitted from the emitting layer 218 may pass through the layer 222. In some embodiments, the layer 222 has a high work function which promotes injection of holes into the HOMO level of the emitting layer 218.

In some embodiments, the layer 224 may include a film having the element material selected from aluminum (Al), silver (Ag), gold (Au), copper (Cu), zinc (Zn), indium (In), tin (Sn), titanium (Ti), zirconium (Zr), hafnium (Ha), niobium (Nb), tantalum (Ta), molybdenum (Mo), tungsten (W), manganese (Mg), iron (Fe), ruthenium (Ru), rhodium (Rh), iridium (Ir), nickel (Ni), palladium (Pb), platinum (Pt), silicon (Si), or germanium (Ge), or combinations thereof. In some embodiments, the layer 224 is opaque to the light emitted from the emitting layer 218. In some embodiments, the light emitted from the emitting layer 218 may be reflected by the layer 224. In some embodiments, the layer 224 is not formed in the second portion 207B.

In some embodiments, the layer 222 is continuous in the first portion 207A and the second portion 207B. In some embodiments, the layer 224 is continuous in the second portion 207B, but not extends to the first portion 207A. The second portion 207B is defined as a portion that consisted of both the layer 222 and the layer 224. The first portion 207A is defined as a portion that does not contain the layer 224. In some embodiments, the boundary between the first portion 207A and the second portion 207B is also a boundary of the layer 224.

In some embodiments, the second portion 207B is consisted of the layer 224 sandwiched in the layer 222. In some embodiments, in the second portion 207B, the layer 224 is encircled in the layer 222.

In some embodiments, a thickness of the first portion 207A measured in the vertical direction D1 is thinner than that of the second portion 207B. In some embodiments, the layer 222 concaves in the first portion 207A, forming a recession in the first portion 207A.

In some embodiments, the bump 210 covers a corner of the first portion 207A. In some embodiments, the bump 210 covers a corner of the layer 222 in the first portion 207A. In some embodiments, the bump 212 covers a corner of the second portion 207B.

In some embodiments, the light sensing region 206 and the second portion 207B are staggered in the vertical direction D1. In some embodiments, the light sensing region 206 and the second portion 207B are not overlapped in the vertical direction D1. In some embodiments, the light sensing region 206 and the first portion 207A are partially overlapped in the vertical direction D1.

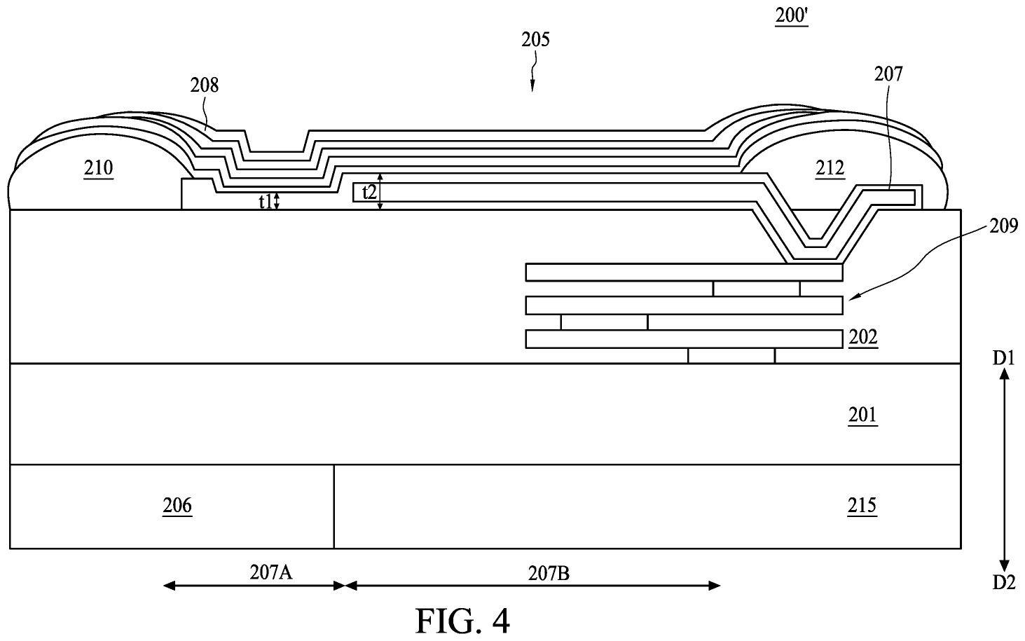

Referring to FIG. 4, FIG. 4 illustrates a cross-sectional view of a pixel of a light emitting device 200′, in accordance with some embodiments of the present disclosure. Since the light emitting device 200′ in FIG. 4 is similar to the light emitting device 200 in described above in relation to FIG. 3, the identical numbers represent similar components for simplicity of explanation. Such similar components are omitted in the interest of brevity, and only the differences are provided.

The light emitting device 200′ further include a second substrate 215 below the TFT layer 201. In some embodiments, the light sensing region 206 is disposed in the second substrate 215. In some embodiments, the TFT layer 201 is between the light sensing region 206 and the first electrode 207. By disposing the light sensing region 206 in a substrate below the TFT layer 201, the manufacturing process for forming the light sensing region 206 may be proceeded parallel to the manufacturing process for forming the other layers.

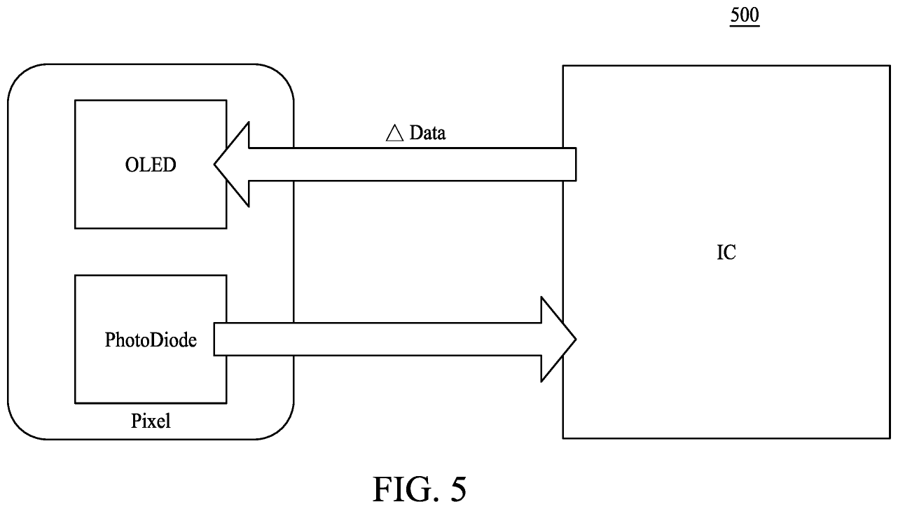

Referring to FIG. 5, FIG. 5 is a functional block diagram 500 of the light emitting device 200 and 200′, in accordance with some embodiments of the present disclosure.

Under certain voltage driving, the emitting layer 218 forms excitons to excite the emission lights. A part of the emission lights is allowed to passing through the first portion 207A to be received on the light sensing portion 206.

The emission light is converted by the light sensing portion 206 into data information. In some embodiments, the emission light absorbed in the light sensing portion 206 converts to charge carriers. In some embodiments, the charge carrier can be positive or negative. The charge carriers flow to a contact plug so as to transfer information about the characteristic of the emission light to the circuitry in the TFT layer 201 for further processing and/or output.

In some embodiments, the light sensing portion 206 is coupled to another semiconductive device, such as a transistor, through the contact plug. Data information is transferred from the transistor to the circuitry in the TFT layer 201.

In some embodiments, the characteristic of the emission light is compared to the standard value by a functional module in the TFT layer 201. In some embodiments, a brightness of the emission light is compared. In some embodiments, since the emission light is sensed by the light sensing portion 206 during an operating time of the light emitting device 200 and 200′, the characteristic of the emission light may be detected immediately and accurately. In some embodiments, if the characteristic is deviated from the standard value, compensation to the voltage may be made in time. For examples, if the brightness of the emission light is detected to be lower than the standard value, the TFT layer 201 may functioned to increase the voltage of the pixel emitting the emission light.

Some embodiments of the present disclosure provide a light emitting device. The light emitting device includes a substrate and a light sensing region in the substrate. The light emitting device also includes a light emitting pixel over the substrate. The light emitting pixel includes a first electrode including a first portion and a second portion. The light emitting pixel also includes a second electrode over the first electrode, and an organic layer disposed between the first electrode and the second electrode in a vertical direction. The first portion allows light emitted from the organic layer to pass through, and the second portion is opaque to the light. The light sensing region is configured to sense the light passing through the first portion from the organic layer.

Some embodiments of the present disclosure provide a light emitting device. The light emitting device includes a first substrate and a second substrate below the first substrate. The light emitting device also includes a light sensing region in the second substrate, and a light emitting pixel over the first substrate. The light emitting pixel includes a first electrode having a recession concave downward to the second substrate. The light emitting pixel also includes a second electrode over the first electrode. The light emitting pixel also includes an organic layer disposed between the first electrode and the second electrode in a vertical direction. The recession is partially overlapped with the light sensing region in the vertical direction.

Some embodiments of the present disclosure provide a method for compensating light emitting device power supply voltage drop using the light emitting device. The method includes applying a voltage to the first electrode, causing the organic layer to emit the light. A part of the light passing through the first portion. The method also includes receiving the part of the light on the light sensing region. The method also includes comparing a brightness of the part of the light with a standard value and making compensation to the voltage.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein, may be utilized according to the present invention. Accordingly, the appended claims are intended to include within their scope such processes, machines, manufacture, compositions of matter, means, methods, or steps.

What is claimed is:

1. A light emitting device, comprising:
a substrate;
a light sensing region in the substrate;
a light emitting pixel over the substrate, comprising:
a first electrode including a first portion and a second portion;
a second electrode over the first electrode;
an organic layer disposed between the first electrode and the second electrode in a vertical direction;
wherein the first portion allows light emitted from the organic layer to pass through, and the second portion is opaque to the light; and
wherein the light sensing region is configured to sense the light passing through the first portion from the organic layer.

2. The light emitting device of claim 1, wherein the light sensing region and the second portion are staggered in the vertical direction.

3. The light emitting device of claim 1, wherein the light sensing region and the first portion are partially overlapped in the vertical direction.

4. The light emitting device of claim 1, further comprising:
a first pixel definition bump, covering a corner of the first portion; and
a second pixel definition bump, covering a corner of the second portion.

5. The light emitting device of claim 1, wherein a thickness of the first portion measured in the vertical direction is thinner than that of the second portion.

6. The light emitting device of claim 1, wherein the first portion comprises an indium tin oxide (ITO) film.

7. The light emitting device of claim 6, wherein the ITO film is continuous in the first portion and the second portion.

8. The light emitting device of claim 1, wherein the second portion comprises the ITO film and an aluminum (Al) film.

9. The light emitting device of claim 8, wherein the Al film is encircled in the ITO film.

10. The light emitting device of claim 1, wherein the ITO film has a recession formed in the first portion.

11. The light emitting device of claim 1, further comprising:
a thin-film transistor (TFT) layer, wherein the light sensing region is between the TFT layer and the first electrode.

12. A light emitting device, comprising:
a first substrate;
a second substrate below the first substrate;
a light sensing region in the second substrate;
a light emitting pixel over the first substrate, comprising:
a first electrode having a recession concave downward to the second substrate;
a second electrode over the first electrode;
an organic layer disposed between the first electrode and the second electrode in a vertical direction;
wherein the recession is partially overlapped with the light sensing region in the vertical direction.

13. The light emitting device of claim 12, wherein the first electrode comprises:
an indium tin oxide (ITO) film; and
an aluminum (Al) film;
wherein the recession is formed in the ITO film.

14. The light emitting device of claim 12, further comprising:
a thin-film transistor (TFT) layer disposed between the first substrate and the second substrate in the vertical direction.

15. A method for compensating light emitting device power supply voltage drop using the light emitting device of claim 1, comprising:
applying a voltage to the first electrode, causing the organic layer to emit the light, wherein a part of the light passing through the first portion;
receiving the part of the light on the light sensing region;
comparing a brightness of the part of the light with a standard value; and
making a compensation to the voltage.
